(19) United States
(12) Patent Application Publication
(10) Pub. No.: US 2007/0080427 A1
(43) Pub. Date: Apr. 12, 2007

(54) Semiconductor device

(76) Inventor: Shingo Takagi, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/509,725

(22) Filed: Aug. 25, 2006

(30) Foreign Application Priority Data
Aug. 26, 2005 (JP) 2005-246331

(51) Int. Cl. H01L 23/52

(52) U.S. Cl. 257/536; 257/734; 257/773

(57) ABSTRACT

A semiconductor device includes semiconductor substrate, a plurality of element forming regions formed on the semiconductor substrate, and an interconnect for connecting the plurality of element forming regions to one another. A concave portion whose upper surface is lower than that of the surfaces of the element forming regions connected by use of the interconnect is formed in the surface of the semiconductor substrate under the interconnect.

### CROSS-REFERENCE TO RELATED APPLICATIONS

This application is based upon and claims the benefit of priority from prior Japanese Patent Application No. 2005-246331, filed Aug. 26, 2005, the entire contents of which are incorporated herein by reference.

### BACKGROUND OF THE INVENTION

1. Field of the Invention

The present invention relates to a semiconductor device for high speed operation.

2. Descriptions of the Related Art

Recently, the minimum line width in a process of manufacturing semiconductor devices has been reduced, and dielectric or insulating films have been thinner. In addition, transmission signals in the semiconductor device have flown at a higher speed and had higher frequencies. Accordingly, it becomes prominent that the transmission signals deteriorate due to influence of parasitic elements.

As for a method of reducing the influence of parasitic elements, a low-permittivity insulator is used as an interlayer dielectric between interconnects and a substrate. In addition, a method has been proposed of enlarging a thickness of an interlayer dielectric between the interconnects and the substrate has a larger thickness, in other words, of designing the distance between interconnects and a semiconductor substrate to be larger (for example, refer to Japanese Patent Application Laid-Open No. 2002-57215 and Japanese Patent Application Laid-Open No. Hei 5-211243).

Although each of the methods can provide an effect of reducing the influence of the parasitic elements, the methods cause the height of space necessary for interconnects to become larger. Hence, there is a problem that such methods are not suitable for a manufacturing process using the smaller minimum line width.

### SUMMARY OF THE INVENTION

According to a first aspect of the present invention, there is provided a semiconductor device comprising: a semiconductor substrate; a plurality of element forming regions formed on the semiconductor substrate; and an interconnect for connecting the plurality of element forming regions to one another, wherein a concave portion whose upper surface is lower than that of the surfaces of the element forming regions connected by use of the interconnect is formed in the surface of the semiconductor substrate under the interconnect.

### BRIEF DESCRIPTION OF THE DRAWINGS

FIG. 1 is a cross sectional view of a semiconductor device of a first example, taken along the line A-A′ shown in FIG. 3.

FIG. 2 is a top view of a semiconductor device of the present invention.

FIG. 3 is an enlarged view of a part of the semiconductor device of FIG. 2.

FIG. 4 is a view illustrating an equivalent circuit indicating a parasitic element of the semiconductor device of the first example.

FIG. 5 is a cross sectional view of a semiconductor device of a second example, taken along the line A-A′ shown in FIG. 3.

FIG. 6 is a view illustrating an equivalent circuit indicating a parasitic element of the semiconductor device of the second example.

FIG. 7 is a cross sectional view of a semiconductor device of a third example, taken along the line A-A′ shown in FIG. 3.

FIG. 8 is illustrating an equivalent circuit indicating a parasitic element of the semiconductor device of the second example.

### DESCRIPTION OF THE PREFERRED EMBODIMENTS

### First Example

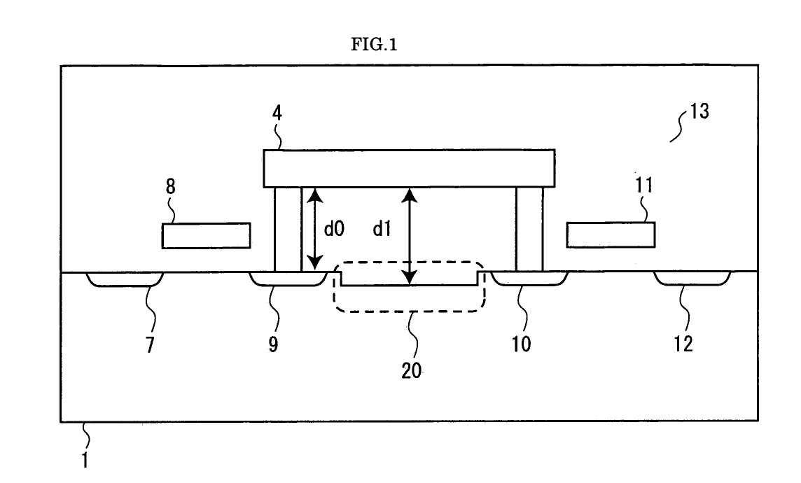

By referring to FIGS. 1 to 4, descriptions will be provided for a semiconductor device of a first example of the present invention.

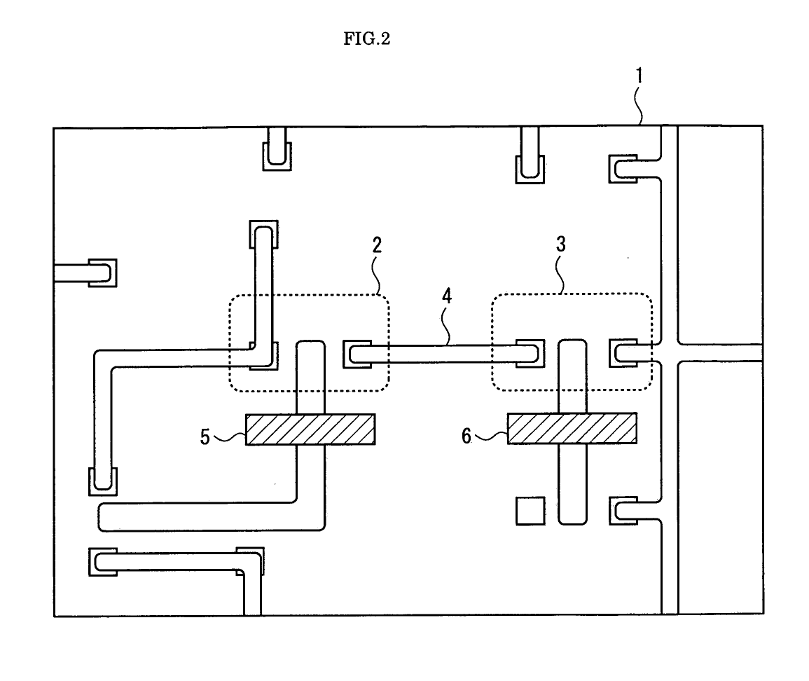

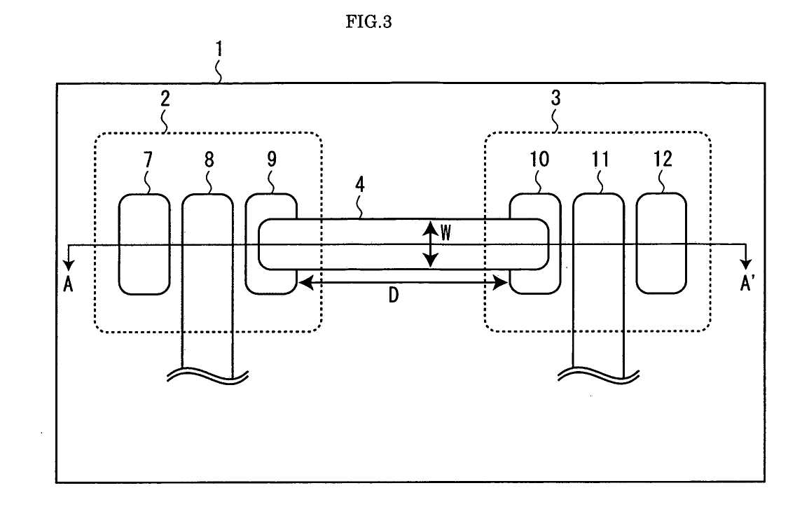

FIG. 1 is a cross sectional view of a semiconductor device of the first example, taken along the line A-A′ shown in FIG. 3. FIG. 2 is a top view of the semiconductor device of the first example. FIG. 3 is an enlarged view of a part of the semiconductor device of FIG. 2.

As illustrated in FIGS. 1 to 3, the semiconductor device of the first example includes a first MOS transistor 2, a second MOS transistor 3, an interconnect 4, a first gate control circuit 5, a second gate control circuit 6, and an interlayer dielectric 13, all of which are on a semiconductor substrate such as a silicon substrate 1.

Each of the first and second MOS transistors 2 and 3 is a device forming region formed on the silicon substrate 1, and functions as a transistor.

The transistor 2 includes a first source 7, a first gate 8 and a first drain 9. The transistor 3 includes a second source 10, a second gate 11 and a second drain 12.

The first gate control circuit 5 is connected to the first gate 8, and makes an on/off control of the transistor 2. The second gate control circuit 6 is connected to the second gate 11, and makes an on/off control of the transistor 3.

The first drain 9 and the second source 10 are connected to each other via the interconnect 4. The first source 7 and the second drain 12 are connected respectively to other elements not illustrated in FIG. 3 via interconnects not illustrated in FIG. 3.

In the semiconductor device of the first example, the width W of the interconnect 4 is 90 nm, and the distance D between the first drain 9 and the second source 10 is approximately 400 nm.

A concave portion 20 is formed in the upper surface of the silicon substrate 1 under the interconnect 4. The concave portion 20 has a linear groove shape. The width of the concave portion 20 is approximately 90 nm which is approximately equal to the width W of the interconnect 4. The length of the concave portion 20 is approximately 400 nm which is approximately equal to the distance D between the first drain 9 and the second source 10. The depth of the concave portion 20 is approximately 25 nm which is approximately equal to each of the depths of the first drain 9 and the second source 10. The concave portion 20 is formed by etching, for example, by anisotropic etching, the upper surface of the silicon substrate 1 to a predetermined depth.

The distance d0 between the upper surface of the silicon substrate 1 and the lower surface of the interconnect 4 is approximately 250 nm. The distance d1 between the bottom surface of the concave portion 20 in the upper surface of the silicon substrate 1 and the lower surface of the interconnect 4 is approximately 275 nm.

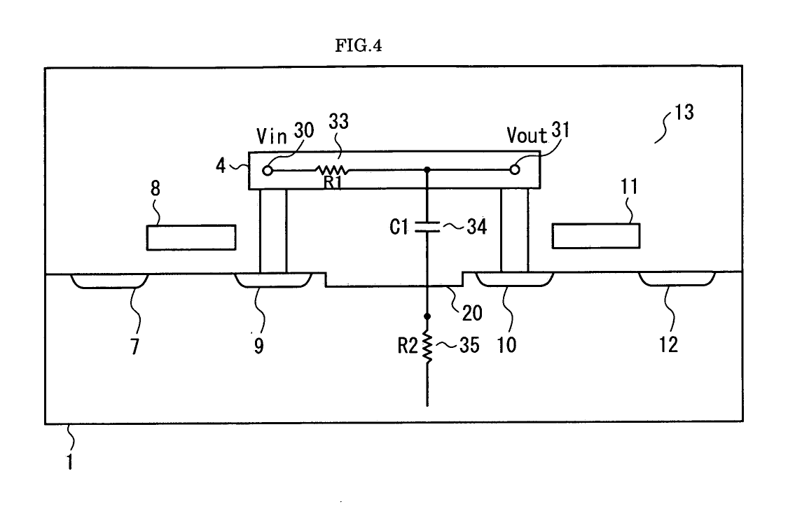

Subsequently, with reference to FIG. 4 and equations, descriptions will be provided for an effect of the concave portion 20.

FIG. 4 is a view illustrating an equivalent circuit indicating a parasitic element of the case where a transmission signal flows from the first drain 9 to the second source 10 through the interconnect 4. The transmission signal flows from an input terminal 30 to an output terminal 31, both located on the interconnect 4.

The interconnect 4 is shown as a first resistance component 33 of a resistance value R₁. The distance between the lower surface of the interconnect 4 and the bottom surface of the concave portion 20 is shown as a capacitor component 34 of a capacitor C₁. The silicon substrate 1 is shown as a second resistance component 35 of a resistance value R₂.

The capacitance C of the capacitor is represented by
C=ε×(s/d),
where s, d, ε denote respectively the area of electrodes of a capacitor, the distance between the electrodes of the capacitor, and the permittivity of a dielectric interposed between the electrodes of the capacitor. In other words the capacitance of the capacitor is inversely proportional to the distance between the electrodes.

Since the concave portion 20 is formed in the semiconductor device of the first example, the distance d1 between the lower surface of the interconnect 4 and the bottom surface of the concave portion 20 is 10% longer than the distance d0 between the lower surface of the interconnect 4 and the upper surface of the silicon substrate 1. Here, let C₀ denote the capacitance of the capacitor of the case where the concave portion 20 is not formed. The capacitance C₁ of the first capacitor component 34 is 9% smaller than the capacitance C₀, when the capacitance C₁ is calculated back to based on the fact that d1 is approximately 10% longer than d0.

As shown in FIG. 4, Vᵢₙ and Vₒᵤₜ denote respectively a voltage applied to the input terminal 30 and a voltage outputted from the output terminal 31. In the case where the transmission signal flows through the interconnect 4, the equivalent circuit including the parasitic element functions as a low-pass filter. In other words, Vᵢₙ is attenuated due to the influence of the low-pass filter, and the attenuated Vᵢₙ is outputted as Vₒᵤₜ.

When H1 denotes the transfer function of the low-pass filter, H1 is represented by,
H1=Vₒᵤₜ/Vᵢₙ.
Here, when the denominator of the transfer function is 0, the frequency is the cutoff frequency. When the cutoff frequency is defined as Fp, Fp of the semiconductor device of the first example is represented as follows,

$$Fp = \frac{1}{2 π {C}_{1} ( {R}_{1} + {R}_{2} )} . \qquad ( 1 )$$

As can be seen from the equation (1), the cutoff frequency Fp is inversely proportional to the capacitance C₁. In other words, the smaller the capacitance C₁ becomes, the higher the cutoff frequency Fp becomes. This means that Fp shifts toward a higher frequency.

When the transmission signal contains a rectangular wave, rise and fall times of a transmission signal generally need to be shorter in order to ensure a sampling time, as a rate of the transmission signal becomes faster. In other words, the shorter rise and fall times of the transmission signal allows the transmission signal to contain a higher frequency component. That is, as the transmission signal flows at a higher speed, even the higher frequency component needs to flow through the interconnect 4.

In the semiconductor device of the first example, the capacitance C₁ of the first capacitor component 34 is 9% smaller than that of the case where the concave portion 20 is not formed. Accordingly, as can be seen from the equation (1), the cutoff frequency is 10% higher. This allows the frequency component of the approximately 10% higher frequency to flow through the interconnect 4. Consequently, the faster transmission signal flows through the interconnect 4 than that of the case where the concave portion 20 is not formed.

As described above, since the semiconductor device of the first example has a configuration in which the upper surface of the silicon substrate 1 is etched, it is not necessary to build up, for example, an interlayer dielectric to a height more than that of a usually formed interlayer dielectric. Accordingly, the semiconductor device is suitable for the manufacturing process using the smaller minimum line-width.

In addition, the concave portion 20 may be formed together with a different portion such as an element isolation region in one manufacturing step, by using, for example, the anisotropic etching technique. Accordingly, the concave portion 20 may be formed without adding an additional step to the steps of predetermined manufacturing processes.

The capacitance C₁ may be changed depending on the depth of the concave portion 20. The semiconductor device of the first example has a configuration in which the capacitance C₁ is 9% lower than that of the case where the concave portion 20 is not formed. However, another arbitral capacitance may be adopted.

The first example shows the example of the semiconductor device in which the concave portion 20 has the liner groove shape. However, any shape may be adopted, as long as the concave portion 20 is formed by etching down the upper surface of the silicon substrate 1 under the interconnect 4 to obtain the similar effect.

The first example shows the example of the semiconductor device in which the concave portion 20 has the width approximately equal to the width W of the interconnect 4, and has the length approximately equal to the distance D between the first drain 9 and the second source 10. However, the concave portion 20 may have a shape with a larger or smaller width and a shorter length than those of the first example, as long as the concave portion 20 is formed by etching down the upper surface of the silicon substrate 1 under the interconnect 4 to obtain the similar effect.

### Second Example

By referring to FIGS. 2, 3, 5 and 6, descriptions will be provided for a semiconductor device of a second example of the present invention.

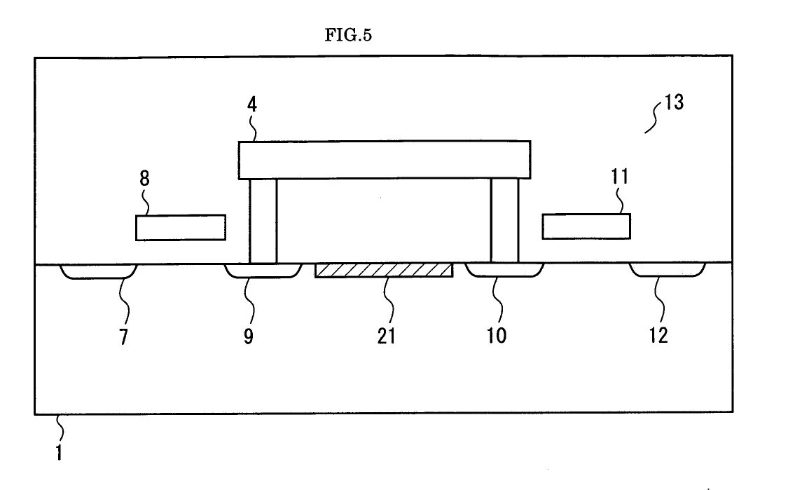

FIG. 5 is a cross sectional view of a semiconductor device of the second example, taken along the line A-A′ shown in FIG. 3. FIG. 2 is a top view of the semiconductor device of the second example. FIG. 3 is an enlarged view of a part of the semiconductor device of FIG. 2.

As illustrated in FIGS. 2, 3 and 5, the semiconductor device of the second example includes a first MOS transistor 2, a second MOS transistor 3, an interconnect 4, a first gate control circuit 5, a second gate control circuit 6 and an interlayer dielectric 13, all of which are on a silicon substrate 1 as in the case of the first example. Descriptions of the configuration of these circuits are omitted here, since the configuration is the same as that of the first example.

A concave portion is provided in the upper surface of the silicon substrate 1 under the interconnect 4. A resistive load part 21 is formed in the concave portion. The resistive load part 21 is a resistive region formed along the interconnect 4. The upper surface of the resistive load part 21 is in the same plane as the upper surface of the silicon substrate 1.

The width of the resistive load part 21 is approximately 90 nm which is approximately equal to the width W of the interconnect 4. The length of the resistive load part 21 is approximately 400 nm which is approximately equal to a distance D between the first drain 9 and the second source 10. The thickness of the resistive load part 21 is approximately 25 nm which is approximately equal to the depths of the first drain 9 and the second source 10.

The resistive load part 21 is a region having a resistance higher than that of the silicon substrate 1. In the semiconductor device of the second example, the silicon substrate 1 is p-type silicon and has a resistance of 10⁰ Ω·cm, while the resistive load part 21 has a resistance of 10⁴ Ω·cm.

The resistive load part 21 is formed, for instance, by etching the silicon substrate 1, and then, by burying an insulator or a high-load substance in the etched portion. Alternatively, the resistive load part 21 may be formed by directly doping the silicon substrate with a high resistance substance by ion implantation, and then, by annealing the substrate 1.

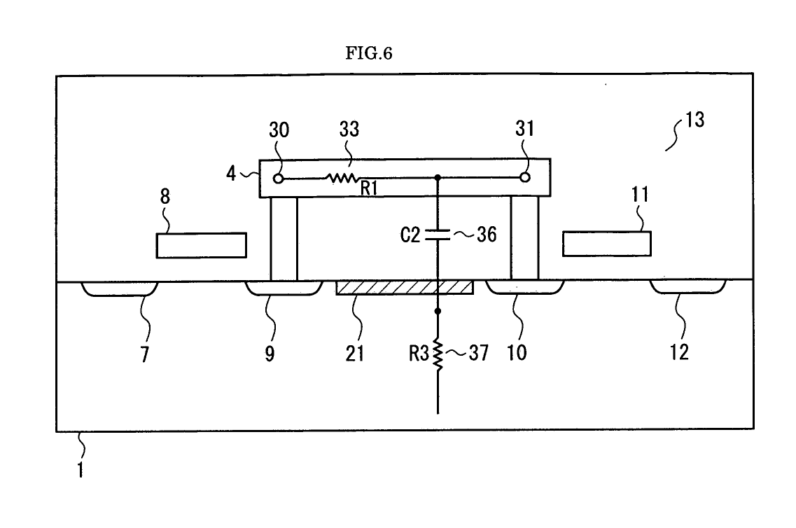

Subsequently, descriptions will be provided for an effect of the resistive load part 21 with reference to FIG. 6 and equations.

FIG. 6 is a view illustrating an equivalent circuit indicating a parasitic element of the case where a transmission signal flows from the first drain 9 to the second source 10 through the interconnect 4. The transmission signal flows from an input terminal 30 to an output terminal 31 through the interconnect 4.

The interconnect 4 is shown as a first resistance component 33 of a resistance value R₁. The distance between the interconnect 4 and the silicon substrate 1 is shown as a capacitor component 36 of a capacitance C₂. The silicon substrate 1 is shown as a third resistance component 37 of a resistance value R₃.

Here, Vᵢₙ and Vₒᵤₜ respectively denote a voltage applied to the interconnect 4 and a voltage outputted from the interconnect 4. In the case where a signal flows from the first drain 9 to the second source 10 through the interconnect 4, the equivalent circuit including the parasitic element function as a low-pass filter as in the case of the first example.

As illustrated in FIG. 6, Vᵢₙ and Vₒᵤₜ denote respectively a voltage applied to the input terminal 30 and a voltage outputted from the output terminal 31. In this case, the equivalent circuit including the parasitic element functions as the low-pass filter. In other words, Vᵢₙ is attenuated due to the influence of the low-pass filter, and the attenuated Vᵢₙ is outputted as Vₒᵤₜ.

Let H2 be the transfer function of the low-pass filter. The transfer function is represented by
H2=Vₒᵤₜ/Vᵢₙ.
Here, let f denotes a frequency. If ω2πf and s=jω, H2(s)is calculated by

$$H 2 ( s ) = \frac{{V}_{out}}{{V}_{in}} = \frac{1 + {sC}_{2} {R}_{3}}{1 + {sC}_{2} ( {R}_{1} + {R}_{3} )} . \qquad ( 2 )$$

With regard to the equation, the impedance 1/sC₂ of the capacitance C₂ is close to 0 in a higher frequency domain above the cutoff frequency Fp described in the first example. For this reason, the value of Vₒᵤₜ may be calculated by the following equation:

$${V}_{out} = \frac{{R}_{3}}{{R}_{1} + {R}_{3}} \cdot {V}_{in} . \qquad ( 3 )$$

As shown in the equation (3), Vₒᵤₜ is obtained by dividing Vᵢₙ by the first and third resistance components 33 and 37 In other words, as the third resistance component 37 increases, Vₒᵤₜ increases.

In the semiconductor device of the second example, the resistance value R₃ of the third resistance component 37 is larger than that of the case where the resistive load part 21 is not formed. For this reason, Vₒᵤₜ becomes larger in the higher frequency domain above the cutoff frequency. This facilitates the flow of the higher frequency component through the interconnect 4, and the transmission signal is transmitted at a high speed with little attenuation as compared with the case where the resistive load part 21 is not formed.

Moreover, the semiconductor device of the second example makes it possible to further facilitate the flow of the frequency component in the higher frequency domain above the cutoff frequency.

The semiconductor device of the second example has a configuration in which the resistive load part 21 is buried in the upper surface of the silicon substrate 1. Hence, it is not necessary to build up an interlayer dielectric to a height more than that of a usually formed interlayer dielectric. Accordingly, the semiconductor device is particularly suitable for a manufacturing process using the smaller minimum line-width.

In addition, the resistive load part 21 may be formed together with, for example, an element isolation region in a single manufacturing step, by using the anisotropic etching technique or the ion implantation method. Accordingly, the resistive load part 21 may be formed without adding an additional step to the steps of predetermined manufacturing processes.

In addition, the resistance of the resistive load part 21 may be changed by changing a material of the high-load substance to be used or the shape of the resistive load part 21. In the semiconductor device of the second example, the resistance of the resistive load part 21 is 10⁴ Ω·cm, but another arbitral value of resistance may be adopted.

The second example shows the example of the semiconductor device in which the resistive load part 21 is formed along the interconnect 4. However, another arbitral shape may be adopted as long as the resistive load part 21 is formed under the interconnect 4 to obtain the similar effect.

The second example shows the example of the semiconductor device in which the resistive load part 21 has the width approximately equal to the width W of the interconnect 4 and the length approximately equal to the distance D between the first drain 9 and the second source 10. However, the resistive load part 21 may have a shape with a larger or smaller width and with a shorter length than those of the first example, as long as the resistive load part 21 is formed under the interconnect 4 to obtain the similar effect.

In addition, in the second example, the example of the semiconductor device has the configuration, in which the resistive load portion 21 is buried in the upper surface of the silicon substrate 1. However, it is also possible to adopt a configuration obtained by forming a concave portion in the upper surface of the silicon substrate 1 and by depositing the resistive load part 21 in the concave portion.

### Third Example

By referring to FIGS. 2, 3, 7 and 8, descriptions will be provided for a semiconductor device of a third example of the present invention.

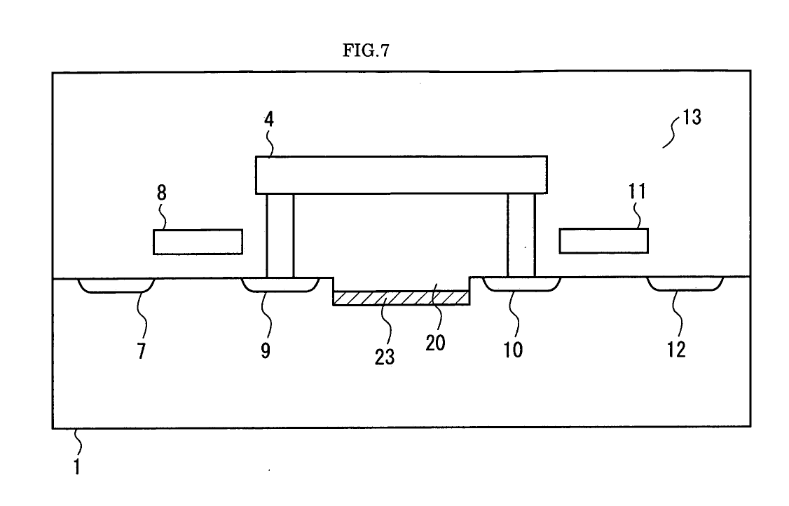

FIG. 7 is a cross sectional view of a semiconductor device of the third example taken along the line A-A′ shown in FIG. 3. FIG. 2 is a top view of the semiconductor device of the second example. FIG. 3 is an enlarged view of a part of the semiconductor device of FIG. 2.

As illustrated in FIGS. 2, 3 and 7, the semiconductor device of the third example includes a first MOS transistor 2, a second MOS transistor 3, an interconnect 4, a first gate control circuit 5, a second gate control circuit 6, and an interlayer dielectric 13, all of which are on a semiconductor substrate 1, as in the case of the first example. Descriptions for the configuration of the circuits are omitted here, since the configurations is the same as that of the first example.

A concave portion 20 is formed in the upper surface of the silicon substrate 1 under the interconnect 4. As in the case of the first example, the concave portion 20 has a linear groove shape and has a width, a length and a thickness which are approximately 90 nm, approximately 400 nm and approximately 25 nm, respectively.

A resistive load part 23 is formed in the bottom surface of the concave portion 20. As in the case of the resistive load part 21 described in the second example, the resistive load part 23 is formed along the interconnect 4, and is a resistive region having a resistance higher than that of the silicon substrate 1. The resistive load part 23 has a width, a length and a thickness which are approximately 90 nm, approximately 400 nm and approximately 25 nm, respectively.

In the semiconductor device of the third example, the silicon substrate 1 is p-type silicon and has a resistance of 10⁰ Ω·cm, while the resistive load part 23 has a resistance of 10⁴ Ω·cm.

As in the case of the first example, the concave portion 20 is formed by etching the upper surface of the silicon substrate 1 to a predetermined depth by, for instance, anisotropic etching.

After the concave portion 20 is formed, the resistive load part 23 is formed, for instance, by etching the silicon substrate 1 under the concave portion 20, and then, by burying an insulator or a high-load substance in the etched portion. Alternatively, the resistive load part 23 may be formed by directly doping the silicon substrate 1 with a high resistance substance by ion implantation, and then, by annealing the silicon substrate 1.

As in the case of the first example, the distance d0 between the silicon substrate 1 and the lower surface of the interconnect 4 is approximately 250 nm, and the distance d1 between the silicon substrate 1 and the bottom surface of the concave portion 20 is approximately 275 nm.

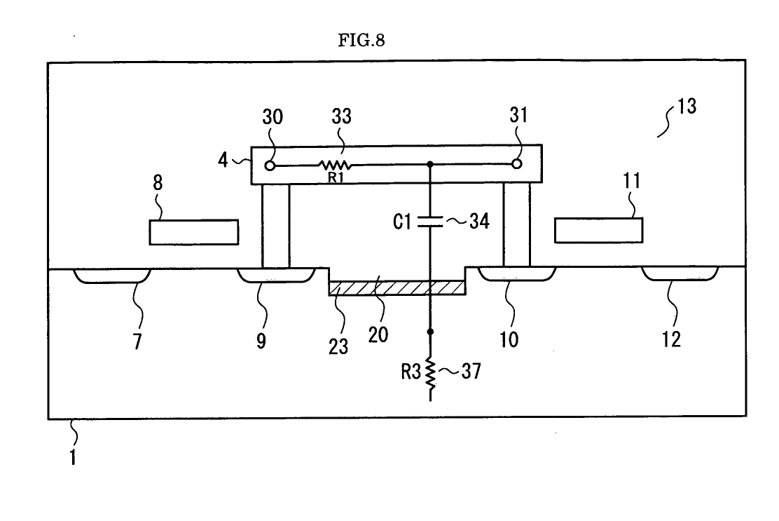

Descriptions will be provided below for an effect of the resistive load part 23 with reference to FIG. 8 and equations.

FIG. 8 is a view illustrating an equivalent circuit indicating a parasitic element of the case where a transmission signal flows from the first drain 9 to the second source 10 through the interconnect 4. The transmission signal flows from an input terminal 30 to an output terminal 31 through the interconnect 4.

The interconnect 4 is shown as a first resistance component 31 of a resistance value R₁. The distance between the interconnect 4 and the silicon substrate 1 is shown as a capacitor component 34 of a capacitance C₁. The silicon substrate 1 having the resistive load part 23 is shown as a third resistance component 37 of a resistance value R₃.

Here, Vᵢₙ and Vₒᵤₜ respectively denote a voltage applied to the interconnect 4 and a voltage outputted from the interconnect 4. In the case where a transmission signal flows from the first drain 9 to the second source 10 through the interconnect 4, the equivalent circuit including the parasitic element functions as a low-pass filter as in the case of the first and second examples.

In the semiconductor device of the third example, the capacitance C₁ of the first capacitor component 34 is 9% smaller than that of the case where the concave portion 20 is not formed. Accordingly, as described in the first example, the faster transmission signal flows through the interconnect 4 than that of the case where the concave portion 20 is not formed.

In the semiconductor device of the third example, the resistance value R₃ of the third resistive component 37 is larger than that of the case where the resistive load part 23 is not formed. Hence, this facilitates the flow of the frequency component through the interconnect 4 in the higher frequency domain above the cutoff frequency, as is the case with the effect of the resistive load part 21 described in the second example. Thus, the transmission signal is transmitted at a high speed with little attenuation as compared with the case where the resistive load part 23 is not formed.

As described above, the transmission signal is transmitted at a high speed with little attenuation in the higher frequency domain above the cutoff frequency in the semiconductor device of the third example. In addition, the cutoff frequency shifts toward the higher frequency. In other words, the semiconductor device of the third example makes it possible to facilitate the flow of the higher frequency component through the interconnect 4.

Since the semiconductor device of the third example has a configuration in which the upper surface of the silicon substrate 1 is etched down to form the concave portion 20, it is not necessary to build up, for example, an interlayer dielectric to a height more than that of a usually formed interlayer dielectric. In addition, since the resistive load part 23 is buried in the bottom surface of the concave portion 20, it is also not necessary to build up an interlayer dielectric to a height more than that of a usually formed interlayer dielectric. Accordingly, the semiconductor device is especially suitable for the manufacturing process using the smaller minimum line-width.

In the semiconductor device of the third example, the concave portion 20 and the resistive load part 23 may be formed together with, for example, an element isolation region in a single manufacturing step, by using the anisotropic etching technique or the ion implantation method. Thereby, the concave portion 20 and the resistive load part 23 may be formed together with a different part in a single step as in the case of the second first and second examples without adding an additional step to the steps of predetermined manufacturing processes.

Furthermore, the capacitance C₁ may be changed depending on the depth of the concave portion 20 as in the case of the first example. Accordingly, another arbitral capacitance may be adopted, although the semiconductor device of the third example has a configuration in which the capacitance C₁, is 9% smaller than that of the case where the concave portion 20 is not formed.

As in the case of the second example, the resistance of the resistive load part 23 may be changed by changing a material of the high-load substance to be used or the shape of the resistive load part 23. Accordingly, another arbitral value may be adopted, although the resistance of the resistive load part 23 is 10⁴ Ω·cm in the semiconductor device of the third example.

The third example shows the example of the semiconductor device in which the concave portion 20 has the liner groove shape. However, any arbitral shape may be taken, as long as the concave portion 20 is formed by etching down the upper surface of the silicon substrate 1 under the interconnect 4 to obtain the similar effect.

The third example shows the example of the semiconductor device in which the concave portion 20 has the width approximately equal to the width W of the interconnect 4 and the length almost equal to the distance D between the first drain 9 and the second source 10. However, the concave portion 20 may have a shape with a larger or smaller width and a shorter length than those of the third example, as long as the concave portion 20 is formed by etching down the upper surface of the silicon substrate 1 under the interconnect 4 to obtain the similar effect.

The third example shows the example of the semiconductor device in which the resistive load part 23 is formed along the interconnect 4. However, another arbitral shape may be adopted as long as the resistive load part 23 is formed under the interconnect 4 to obtain the similar effect.

The third example shows the example of the semiconductor device in which the resistive load part 23 has the width approximately equal to the width W of the interconnect 4 and the length almost equal to the distance D between the first drain 9 and the second source 10. However, the resistive load part 23 may have a shape with a larger or smaller width and a shorter length than those of the third example, as long as the resistive load part 23 is formed under the interconnect 4 to obtain the similar effect.

Furthermore, the third example shows the example that the resistive load part 23 is configured by being buried in the bottom surface of the concave portion 20 in the silicon substrate 1. However, the resistive load part 23 may be configured by etching the bottom surface of the concave portion, and then, by depositing the resistive load part 23.

### (Other Embodiments)

In each of the semiconductor devices of the first to the third examples of the present invention, the first source 7, the first drain 9, the second source 10 and the second drain 12 are formed in this order, from left to right, as illustrated in FIGS. 1 to 8. However, it is also possible to have a configuration in which the positions of the sources are replaced respectively with the positions of the corresponding drains. That is, the configuration may be adopted as well in which the first drain 9, the first source 7, the second drain 12, and the second source 10 are formed in this order, from left to right.

In each of the first to third examples, the example of the semiconductor device including the MOS transistor is shown. However, the semiconductor device may consist of a capacitor or a bipolar transistor which have a trench-structure.

Each of the semiconductor devices of the first to third examples of the present invention includes the interlayer dielectric 13. However, the semiconductor device may be configured by using a substance having a lower permittivity in place of the interlayer dielectric 13 to further reduce the capacitances C₁ and C₂ respectively of the first and second capacitor components 34 and 36.

In each of the semiconductor devices of the first to third examples of the present invention, the concave portion 20, the resistive load part 21 and the resistive load part 23 are formed in the surface of the silicon substrate 1. However, it is also possible to have a configuration in which the concave portion 20, the resistive load part 21 and the resistive load part 23 are formed in a region in, for example, a p-type well or an n-type well in the semiconductor substrate as long as they are provided under the interconnect 4.

Each of the semiconductor devices of the first to third examples of the present invention has a multilevel interconnect structure. Although each of the examples illustrates only the region around the interconnect 4 of the semiconductor device, it is also possible to have a configuration in which an unillustrated interconnect is provided above the interconnect 4.

Each of the semiconductor devices of the first to third examples of the present invention may be configured of the interconnect 4 made of an arbitral interconnect material in addition to aluminum interconnect, aluminum-copper interconnect or copper interconnect.

Each of the first to third examples of the present invention shows, for instance, the lengths and widths of the interconnect 4 and the concave portion 20 of the semiconductor device 20. However, a different length and a different width of each of the interconnect 4 and the concave portion 20 may be adopted to configure the semiconductor device depending on a generation of manufacturing processes to be used or a type of circuit to be used.

Although the present invention has been described with the examples and embodiments as described above, the descriptions and drawings constituting a part of the disclosure simply illustrate the devices and the methods for embodying the technical idea of the invention. Accordingly, the technical idea of the present invention does not limit the configuration of the components, positions thereof and the like to those described in the above examples and embodiments. Various modifications may be made to the technical idea of the present invention within the scope of claims.

What is claimed is:

1. A semiconductor device comprising:
a semiconductor substrate;
a plurality of element forming regions formed on the semiconductor substrate; and
an interconnect for connecting the plurality of element forming regions to one another,
wherein a concave portion whose upper surface is lower than that of the surfaces of the element forming regions connected by use of the interconnect is formed in the surface of the semiconductor substrate under the interconnect.

2. A semiconductor device comprising:
a semiconductor substrate;
a plurality of element forming regions formed on the semiconductor substrate;
an interconnect for connecting the plurality of element forming regions to one another; and
a resistive load part which is formed under the interconnect, and which has a resistance higher than a resistance of the semiconductor substrate.

3. The semiconductor device according to claim 1, wherein a resistive load part having a resistance higher than that of the semiconductor substrate is formed in contact with the bottom surface of the concave portion.
